(19) United States
(12) Patent Application Publication
(10) Pub. No.: US 2024/0160802 A1
(43) Pub. Date: May 16, 2024

(54) REINFORCEMENT LEARNING AND NONLINEAR PROGRAMMING BASED SYSTEM DESIGN

(71) Applicant: Palo Alto Research Center Incorporated, Palo Alto, CA (US)

(72) Inventors: Ion Matei, Mountain View, CA (US); Maksym I. Zhenirovskyy, San Jose, CA (US); Johan de Kleer, Los Altos, CA (US)

(73) Assignee: Palo Alto Research Center Incorporated, Palo Alto, CA (US)

(21) Appl. No.: 17/978,917

(22) Filed: Nov. 1, 2022

(51) Int. Cl. G06F 30/20

(52) U.S. Cl. CPC G06F 30/20

(57) ABSTRACT

One embodiment provides a method for automated design of a physical system. The method can include obtaining design requirements associated with the physical system and iteratively performing, by a computer, a reinforcement learning (RL) process and a nonlinear optimization process to generate a design solution. The RL process can generate a topology represented as a model of the physical system using a modeling language. The generated topology can specify a number of components and connections among the components. The nonlinear optimization process can determine parameters of the components in the topology based on the model and a loss function. The method can further include outputting the design solution of the physical system based on the generated topology and the determined parameters of the components, thereby facilitating construction of the physical system.

### BACKGROUND

### Field

This disclosure is generally related to automated design of physical systems.

### Related Art

Automated design of physical systems is the next frontier in artificial intelligence (AI). Given a set of behavior requirements of a physical system and a library of components that can be used in the design solution, designing the physical system typically can involve two steps, a topology-selection step and a parameter-calibration step. The topology-selection step can involve solving a combinatorial (or discrete) optimization problem, the solution of which describes the system topology and specifies the components needed to create the topology. The parameter-calibration step can involve solving a continuous optimization problem to select parameters of the components in order to meet the system behavior requirements. Solving these two optimization problems for arbitrary physical systems can be challenging.

### SUMMARY

One embodiment provides a method for automated design of a physical system. The method can include obtaining design requirements associated with the physical system and iteratively performing a reinforcement learning (RL) process and a nonlinear optimization process to generate a design solution. The RL process can generate a topology represented as a model of the physical system using a modeling language. The generated topology can specify a number of components and connections among the components. The nonlinear optimization process can determine parameters of the components in the topology based on the model and a loss function. The method can further include outputting the design solution of the physical system based on the generated topology and the determined parameters of the components, thereby facilitating construction of the physical system.

In a variation on this embodiment, performing the RL process can include defining a reward function that encourages sparsity.

In a variation on this embodiment, the generated topology can include a plurality of generalized components. A respective generalized component can include a plurality of switches, with each switch coupled to a component of a particular type, thereby allowing the RL process to select a type of the generalized component by acting on the switches.

In a variation on this embodiment, using the nonlinear optimization process to determine parameters of the components can include generating a Functional Mockup Unit (FMU) and determining the parameters of the components using a gradient-free or gradient-approximation optimization process, which comprises simulating the model and computing the loss function using the FMU.

In a variation on this embodiment, using the nonlinear optimization process to determine parameters of the components can include extracting a set of equations from the model and determining the parameters of the components based on the extracted set of equations using a gradient-based optimization process. The equations specify relationships between a state vector, an algebraic-variables vector, and a parameter vector comprising parameters of the components.

In a further variation, determining the parameters of the components can further include computing a gradient of the loss function by using an ordinary differential equation (ODE) solver to solve the extracted equations.

In a further variation, determining the parameters of the components can further include transforming the extracted set of equations into a set of constraints used in the optimization process.

In a further variation, transforming the equations into the constraints can include performing local parameterization by approximating the state vector using a polynomial between adjacent time instants.

In a further variation, transforming the equations into the constraints can include performing global parameterization by approximating the state vector using a set of orthogonal basis functions.

In a variation on this embodiment, performing the RL process can include training a deep neural network (DNN).

### BRIEF DESCRIPTION OF THE FIGURES

FIG. 1 illustrates an exemplary iterative process for automated system design, according to one embodiment.

FIG. 2 illustrates the design requirements of an electrical circuit.

FIG. 3A illustrates an exemplary initial topology of a to-be-designed electrical circuit, according to one embodiment.

FIG. 3B illustrates an exemplary structure of a generalized component, according to one embodiment.

FIG. 4A illustrates an exemplary circuit topology generated by the RL algorithm, according to one embodiment.

FIG. 4B illustrates the evolution of the reward function computed by the RL scheme and by a random-search scheme, according to one embodiment.

FIG. 4C-1, FIG. 4C-2, and FIG. 4C-3 illustrate an exemplary XML representation of equations extracted from a Modelica model, according to one embodiment.

FIG. 5 presents a flowchart illustrating an exemplary process for designing and constructing a physical system, according to one embodiment.

FIG. 6 presents a block diagram of an exemplary automated system-design apparatus, according to one embodiment.

FIG. 7 illustrates an exemplary computer system that facilitates automated design of physical systems, according to one embodiment.

In the figures, like reference numerals refer to the same figure elements.

### DETAILED DESCRIPTION

The following description is presented to enable any person skilled in the art to make and use the embodiments and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown but is to be accorded the widest scope consistent with the principles and features disclosed herein.

### Overview

Embodiments described herein provide a system and method for automated design of a physical system given a set of system behavior requirements and a library of components. The design problem can be formulated as a mixed-integer optimization problem, which can be solved by combining reinforcement learning (RL) algorithms for topology selection with non-linear programming for calibrating the parameters of the components. The RL problem can be solved using a deep Q-network (DQN) approach, where the Q-function can be approximate using a deep neural network (DNN). Each intermediate topology decided by the RL algorithm can be expressed as a model of the to-be-designed system using a modeling language (e.g., as a Modelica model) and a number of equations that can be extracted from the model. The equations can then be converted into an appropriate format to allow a machine-learning tool (e.g., Pytorch or Jax) to be used to optimize the component parameters. Moreover, a local parameterization or global parameterization scheme can be used to transform the dynamic equations into a set of equality constraints to allow the usage of gradient-based optimization techniques, which can be more efficient and scale better than gradient-free or gradient-approximation algorithms.

### Automated System Design Based on RL and Nonlinear Programming

The problem of designing a physical system can be formulated as a mixed-integer optimization problem

$$( T , P ( T ) ) ,$$

where T is the design topology, P(T) is the set of parameters associated with the topology components, and [symbol] (T,P(T)) is the cost function that measures how closely the design solution meets the design requirements. To solve the above mixed-integer optimization problem, one would need a representation of a design solution (e.g., a modeling language that models the design solution), a mapping from the representation to a set of equations that describe the behavior of the design solution to enable the evaluation of the cost function, and an algorithm to solve the optimization problem based on the set of equations. In some embodiments, an iterative process that includes the processes of topology selection (i.e., determining T) and parameter calibration (i.e., determining P(T)) can be used to achieve the automated system design.

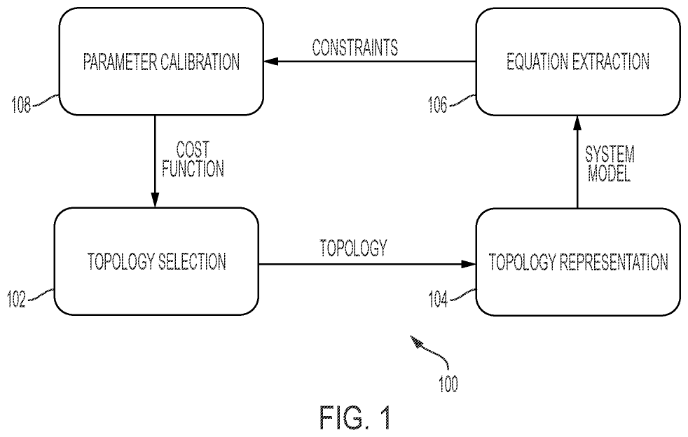

FIG. 1 illustrates an exemplary iterative process for automated system design, according to one embodiment. In FIG. 1, an iterative automated system-design process 100 can include four operations, topology-selection operation 102, topology-representation operation 104, equation-extraction operation 106, and parameter-calibration operation 108. More specifically, topology-selection operation 102 can select or determine a topology based on the value of the cost function (e.g., the selected topology reduces the cost function). The topology of the system can specify a number of components and connections among the components. Topology-representation operation 104 can represent the topology as a model of the to-be-designed system. For example, topology-representation operation 104 can use an appropriate type of modeling language to generate a model of the to-be-designed system to represent the selected topology. Equation-extraction operation 106 can extract a set of equations from the model of the to-be-designed system. The set of equations can be converted into a set of optimization constraints. Parameter-calibration operation 108 can use the constraints and the system requirements to generate component parameters that minimize the cost function.

Using an electrical system (e.g., an analog circuit) as an example, the system topology T can be described as an undirected graph, where the nodes (i.e., electrical domain nodes) in the graph are electrical connection points and the links are basic electrical components (e.g., resistors, capacitors, and inductors). In addition to the above basic electrical components, a link may also include a short component (indicating that the corresponding node or connection point is shorted) or an open component (indicating the corresponding node or connection point is open or has no component). Therefore, each link in topology T of an electrical system can have five possible choices: resistor, capacitor, inductor, short, and open.

Assuming a maximum of N nodes in topology T, then there are a total of N(N−1)/2 links. The cardinality of the set of all topologies [symbol] is

$$\vert = {5}^{\frac{N ( N - 1 )}{2}} .$$

Once a topology is determined or selected, the components on the links need to be instantiated. The process of instantiating the components refers to the process of determining the values of the component parameters (i.e., resistances, capacitances, and inductances). The feasible set of parameters corresponding to a topology T can be denoted [symbol] (T). In the simplest case, [symbol] (T) can correspond to the Cartesian product of the set of non-negative real numbers, since resistances, capacitances, and inductances are all positive.

In some embodiments, solving the topology-selection problem (e.g., determining the layout of an electrical circuit comprising resistors, capacitors, and inductors) can involve applying reinforcement learning (RL), which is a machine-learning technique that can be used to train machine-learning models to make a sequence of decisions. In RL, an agent interacts with a complex and uncertain environment by performing a set of actions to find a solution. The RL problem can be formulated as a Markov decision process (MDP), defined by a tuple [symbol] = [symbol] S, A, R, T, γ, H [symbol] , where S is the state space, A is the action space, R is the reward function, T is the transition function, γ is the scalar discount factor, and H is the time horizon defining the length of an episode.

In the above electrical circuit example, the state space S is the set of all circuit topologies [symbol] and a particular state sₜ is defined as a circuit topology T∈ [symbol] , represented using one-hot encoding. For example, the topology of an RLC circuit comprising a resistor, an inductor, and a capacitor can be represented using [10000, 01000, 00100], where the resistor, inductor, and capacitor are encoded as [10000], [01000], and [00100], respectively.

An action aₜ can represent changes to topology sₜ. The RL algorithm learns a policy π(a, s)=Pr(aₜ=a|sₜ=s) that maximizes the expected cumulative reward. In some embodiments, the reward can be defined to encourage sparsity (i.e., reward topologies with a large number of open connections, or equivalently, topologies with a small number of components) and at the same time penalize topologies that do not meet the required circuit behavior. In one example, the reward can be defined as:

$$r ( s ) = - ( s ) + λ {\sum }_{l} 1 ( l = open ) , \qquad ( 1 )$$

where 1(⋅) is the indicator function, [symbol] * (s) is the optimal cost function after calibrating the parameters of topology T with respect to the circuit behavior requirements, and λ is the weight factor that controls the importance of the topology sparsity. λ can be a user-defined hyper-parameter, which can be determined empirically (e.g., by implementing models with different λs and selecting one λ that results in better performance). The second term (i.e., the sparsity term) in Equation (1) usually is much smaller than the first term, which is dominated by the system behavior.

Solving the MDP means finding an optimal policy (i.e., π*) that maximizes the expected cumulative discounted reward:

$${π}^{*} = arg {max}_{π} E [ {\sum }_{t = 0}^{H} {γ}^{t} R ( {s}_{t} , {a}_{t} ) ] . \qquad ( 2 )$$

In some embodiments, a value-based method can be used to find the optimal policy based on approximations of the value function V(s) (which is the expected discounted reward starting with state s and successively following policy π) and the action-value function Q(s, a) (which is the expected discounted return when in a given state s and for a given action a while following the policy π* thereafter). The value function and the action-value function (or the Q-function) are respectively defined as:

$${V}^{π} ( s ) = E [ {\sum }_{t = 0}^{∞} {γ}^{t} r ( {s}_{t} ) \vert π , {s}_{0} = s ] , \qquad ( 3 )$$

$$and$$

$${Q}^{π} ( s , a ) = E [ {\sum }_{t = 0}^{∞} {γ}^{t} r ( {s}_{t} , {a}_{t} ) \vert π , {s}_{0} = s , {a}_{0} = a ] . \qquad ( 4 )$$

Various techniques can be used to solve the above RL problem (i.e., to find π*). In some embodiments, the RL problem is solved using the Deep Q-network (DQN) approach. In this approach, the Q-function can be approximated using a deep neural network (DNN). The training process can be kept stable by formulating the following loss function:

$$L ( {θ}_{i} ) = {𝔼}_{( s , a , r , {s}^{′} ) □ D} [ {( r + γ {max}_{{a}^{′}} {Q}_{{θ}_{i}^{-}} ( {s}^{′} , {a}^{′} ) - {Q}_{{θ}_{i}} ( s , a ) )}^{2} ] , \qquad ( 5 )$$

where D is a relay buffer used to store (s, a, r, s′) trajectories. By minimizing the above loss function, the current approximation of the Q-function can be pushed towards a maximized target value Q_{θ}_{^{−}}_{ᵢ}(s′,a′).

Depending on the type of system to be designed (e.g., an electrical system, a chemical system, a heating system, a mechanical system, a hydraulic system), the design problem needs to be formulated in an appropriate format to facilitate the execution of the RL algorithm. Formulating the design problem often involves creating a model (typically a mathematical model) of the to-be-designed system using a modeling language. For example, when designing an electrical circuit, a circuit-modeling language, such as Modelica (which is an object-oriented, declarative, multi-domain modeling language for component-oriented modeling of complex systems), can be used during RL to facilitate the computation of the Q-function, the loss function, etc. Other types of circuit-modeling tools or languages (e.g., SPICE or VHDL) can also be used.

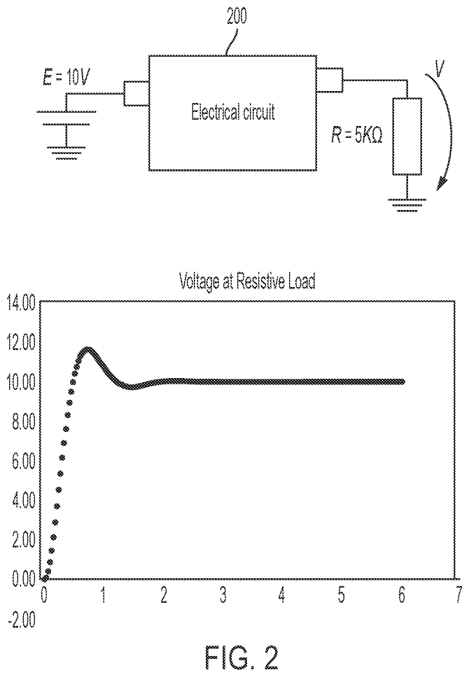

FIG. 2 illustrates the design requirements of an electrical circuit. The top drawing shows a to-be-designed electrical circuit 200, which is coupled to a constant voltage input of 10 V and a resistive load of 5 kΩ, and the bottom drawing shows the voltage output at the resistive load. The automated design of electrical circuit 200 can start with the selection of a topology (or searching over a topology space). In one example, a basic grid structure can be used as an initial topology, with the number of components in the initial topology being the maximum number of components specified by the design requirements.

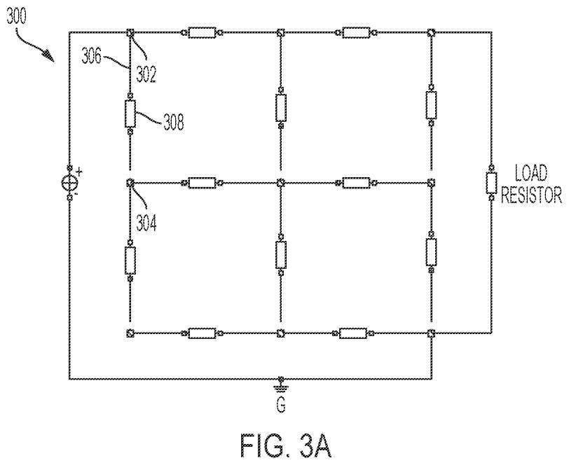

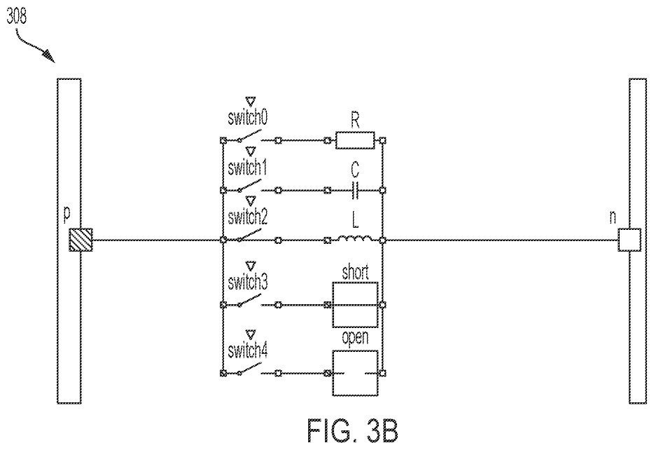

FIG. 3A illustrates an exemplary initial topology of a to-be-designed electrical circuit, according to one embodiment. In FIG. 3A, initial topology 300 can have a grid structure, with each node in the grid (e.g., nodes 302 and 304) being an electrical connection points and each link (e.g., link 306) in the grid structure can include a generalized component (e.g., generalized component 308).

FIG. 3B illustrates the exemplary structure of a generalized component, according to one embodiment. In FIG. 3B, generalized component 308 can include five parallel circuit paths, with each circuit path including a switch and one of the five possible choices of a circuit component (i.e., resistor, capacitor, inductor, short, and open). Generalized component 308 can be instantiated as one of the five possible circuit components by closing one of the switches.

In some embodiments, the RL process can include generating the topologies, including the initial topology (e.g., initial topology 300 shown in FIG. 3A) as well as any intermediate topology determined during the RL process, using a modeling language, such as Modelica. Components in the topology can be instantiated using components from a component library (e.g., the Modelica library). Note that in the example shown in FIG. 3A and FIG. 3B, initial topology 300 and generalized component 308 are both shown as Modelica models, and generalized component 308 can be instantiated as existing components (e.g., resistor, capacitor, inductor, short, and open) in the Modelica library. The topology nodes (e.g., nodes 302 and 304 in FIG. 3A) can be generated using the “connect” command (e.g., to connect equations) in the Modelica language. Note that the current Modelica library contains about 1400 generic model components and 1200 functions in various domains. The RL process does not consider model consistency when generating the Modelica model. Thus, a model-checking process can be executed. The model-checking process is a feature typically included in various tools operating in the Modelica language (e.g., OpenModelica, JModelica, etc.). The model-checking process can check whether there is a sufficient number of equations to simulate the model, or whether there are structural singularities. If the model-checking process fails, the current RL episode can be considered failed, and a small value of the reward function can be returned, signaling that the current topology is not suitable for simulations, let alone for optimization. If the model-checking process succeeds, the topology is declared feasible for simulations and sent to the next stage for further processing.

In the electrical-circuit design example shown in FIGS. 3A-3B, the states are the topology represented using the Modelica language and the actions are the opening and closing of the switches. More particularly, the actions determined by the RL algorithm can act on the switches in each generalized component to activate a particular component type (i.e., resistor, capacitor, inductor, short, or open). Executing the RL algorithm can involve training the DNN approximating the Q-function. During training, the loss function defined in Equation (5) can be minimized to obtain a maximum target value of the approximated Q-function.

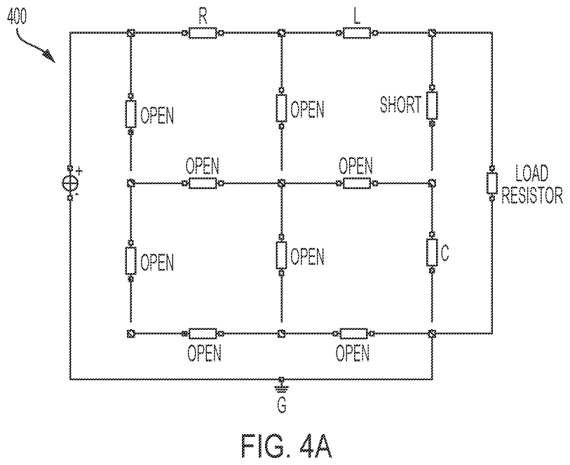

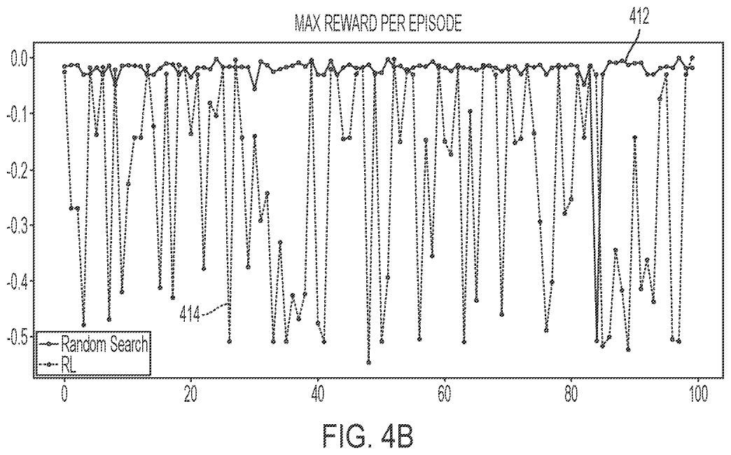

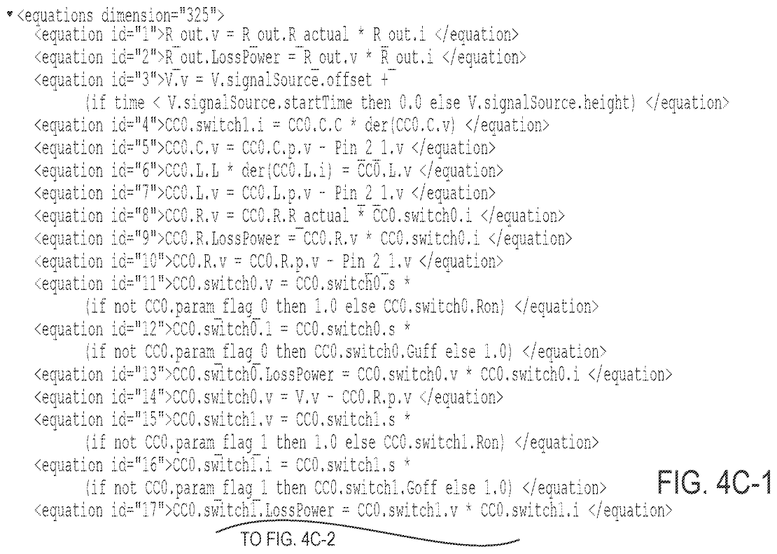

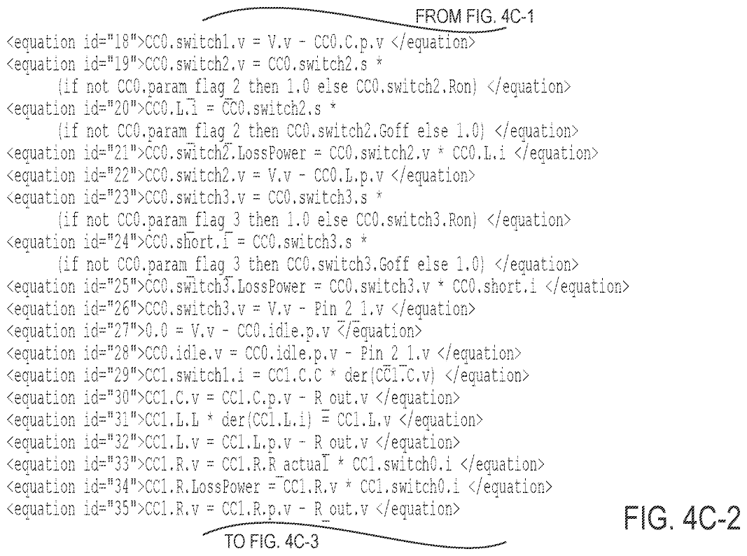

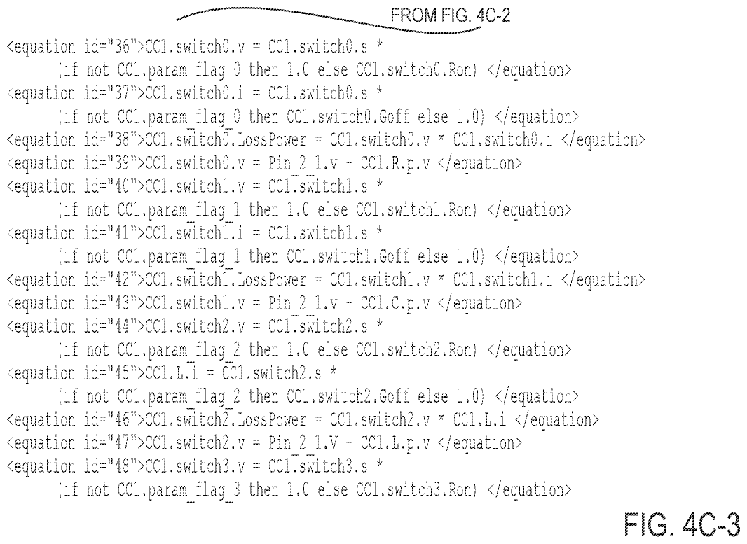

FIG. 4A illustrates an exemplary circuit topology generated by the RL algorithm, according to one embodiment. As can be seen in FIG. 4A, circuit topology 400 can be achieved by instantiating the generalized components in initial circuit topology 300 shown in FIG. 3A. Most circuit components in topology 400 are open components, with the exception of a resistor (R), an inductor (L), a capacitor (C), and a short component.

FIG. 4B illustrates the evolution of the reward function computed by the RL scheme and by a random-search scheme, according to one embodiment. More specifically, a curve 412 shows the reward function as a function of episodes computed by the RL algorithm, and a curve 414 shows the reward function as a function of episodes computed by the random scheme. As can be seen from FIG. 4B, the RL scheme can generate a higher and more stable reward function compared with the oscillating reward function generated by the random-search scheme, in which the topology space is searched randomly. The larger reward function generated by the RL scheme indicates that the RL scheme can generate superior design solutions than the random-search scheme.

After a topology is generated by the RL process, a set of equations governing the behavior of the current design solution (i.e., the current system topology) may be extracted in order to allow the execution of the parameter-calibration process, during which these equations can be used in an optimization formulation to search for component parameters that meet the system design requirements. There are two approaches for the parameter-calibration process, a black-box optimization approach and a white-box optimization approach. Both approaches need to solve the following optimization problem:

$$( p ) , \qquad ( 6 )$$

$$\text{subject to:} F ( \dot{x} , x , u ; p ) = 0 , \qquad ( 7 )$$

where F(\hat{x}, x, u; p)=0 is a differential algebraic equation governing the behavior of the current model, x is the state vector, u is the vector of exogenous inputs (or the algebraic-variables vector), and p is the vector of parameters of the components (or the parameter vector).

In the black-box optimization approach, the model of the system (e.g., the Modelica model of the circuit) can be queried for simulations without the explicit use of the equation F(\hat{x},x,u; p)=0. In some embodiments, a Functional Mockup Unit (FMU) (i.e., a file containing the simulation model of the system) can be generated and integrated into the optimization algorithm to solve (6) and (7). More particularly, the optimization algorithm can use the FMU to simulate the model, evaluate the optimization cost function, and update the optimization variables. However, without the system equations, the optimization algorithm needs to be gradient free or use numerical approximations to compute the loss-function gradients. Using gradient-free algorithms or approximating the gradients typically does not scale well with the number of optimization variables (i.e., the component parameters). Although straightforward to implement, the black-box approach limits the type of optimization algorithms that can be applied and may not be feasible for large-scale systems.

In the white-box optimization approach, the system dynamics (i.e., the differential equations) can be explicitly used as constraints in the optimization process. This way, automatic differential (AD) can be used to compute the gradients of the loss function and the constraints. To perform the white-box optimization, an equation-extraction process is needed to extract equations from the system model (e.g., the Modelica model) generated by the RL process. Depending on the type of modeling language used, various techniques may be used to extract the equations from the system model. For example, the system model can be converted into a text-based format, and the equations can then be extracted from the text. Using the Modelica model as an example, one can use the Open Modelica scripting language (e.g., using the command “dumpXMLDAE”) to generate an Extensible Markup Language (XML) representation of the Modelica model (i.e., to convert the Modelica model from Modelica format into XML format). A flat version of the model can be generated by removing the hierarchy of the model (e.g., there will be no hidden or nested component). The “connect” statements in the XML file can then be replaced with equations reflective of the “connect” statement semantics. FIG. 4C illustrates an exemplary XML representation of equations extracted from a Modelica model, according to one embodiment. More specifically, these equations are extracted from the Modelica model shown in FIGS. 3A-3B. There are a total of 48 equations shown in FIG. 4C. The flat model can be further processed to remove trivial equations (e.g., by using Gaussian elimination). In the example shown in FIG. 4C, after simplification, the total number of equations can be much smaller than 48. The resulting simplified model is often in the form of semi-explicit differential-algebraic equations (DAEs).

In some embodiments, the simplified model can be rebuilt as a Modelica file using the “modelica builder” Python library. The simplified model can also used in the aforementioned black-box approach to simulate the behavior of the current system. In alternative embodiments, these equations are converted into SymPy (an open-source Python library) objects. These Python objects can further be transformed and integrated into an optimization framework featuring automatic differentiation (AD). For example, the Python objects can be converted into objects in a deep-learning or optimization platform (e.g., Pytorch and Jax) and can later be used in optimization algorithms for parameter calibration.

One approach for optimizing the component parameters to get as close as possible to the desired system behavior is to use ordinary differential equation (ODE) solvers while computing the gradients of the loss function. Deep-learning platforms (e.g., Pytorch) often include ODE solvers that support AD, thus enabling the computation of gradients of the loss function. When the model of the to-be-designed system is represented as an ODE, the evaluation of the loss function can include a call to the ODE solver to compute the state vector over a predefined time horizon. However, there is no guarantee that the resulting mathematical model of the system topology is an ODE. At most, it is guaranteed as a semi-explicit DAE, i.e.,

\hat{x}=f(x, z; p), (8)

0=g(x, z; p) (9)

where z is the vector of algebraic variables. In the above case, the optimization formulation has been modified to include time samples of the algebraic variables as optimization variables. Given a set of n time samples {tᵢ}ᵢ₌₀ⁿ⁻¹, the optimization formulation becomes:

$$( T , p , z ( {t}_{i} ) ) , \qquad ( 10 )$$

$$\text{subject to:} {\{ x ( {t}_{i} ) \}}_{i = 0}^{n - 1} = ode solver ( x ( {t}_{0} , {\{ z ( {t}_{i} ) \}}_{i - 0}^{n - 1} , p ) , \qquad ( 11 )$$

$$g ( x ( {t}_{i} ) , z ( {t}_{i} ) ; p ) = 0 , i = 0 , … , n - 1. \qquad ( 12 )$$

The above optimization problem can be solved by adding the weighted algebraic constraints g(x(tᵢ), z(tᵢ); p)=0 to the loss function, where the weights can be updated using a primal-dual method or an augmented Lagrangian method. This ODE-solver-based approach can enable the use of gradient-based optimization algorithms, which scale well with the number of optimization variables. However, the ODE solving process tends to slow down when the number of states increases.

In an alternative approach, rather than calling an ODE solver, the ODE can be transformed into a set of dynamic constraints that can be added to the optimization formulation to facilitate faster convergence of the optimization process.

One way to transform the ODE into dynamic constraints is to use local parameterization of the state vector. In some embodiments, the local parameterization of the state vector can be achieved using a collocation method, where the state vector x(t) is approximated by a polynomial between two consecutive time instants tᵢ and tᵢ₊₁. The solution of the ODE between these two time instants is x(t)=x(tᵢ)+∫ₜ^{t}^{ᵢ₊₁}f′(x(τ), z(τ); p)dτ. Using a second-degree polynomial, the integral can be approximated using the trapezoidal rule, i.e.,

$$x ( {t}_{i + 1} ) = x ( {t}_{i} ) + \frac{h}{2} [ f ( x ( {t}_{i + 1} ) , z ( {t}_{i + 1} ) ; p ) + f ( x ( {t}_{i} ) , z ( {t}_{i} ) ; p ) ] ,$$

where h=tᵢ₊₁−tᵢ. Using this local-parameterization approach, the parameter-calibration problem can be formulated as:

$$( T , p , x ( {t}_{i} ) , z ( {t}_{i} ) ) , \qquad ( 13 )$$

$$\text{subject to:} x ( {t}_{i + 1} ) = x ( {t}_{i} ) + \frac{h}{2} [ f ( x ( {t}_{i + 1} ) , z ( {t}_{i + 1} ) ; p ) + f ( x ( {t}_{i} ) , z ( {t}_{i} ) ; p ) ] , \qquad ( 14 )$$

$$g ( x ( {t}_{i} ) , z ( {t}_{i} ) ; p ) = 0 , i = 0 , … , n - 1. \qquad ( 15 )$$

Although the above optimization problem has a larger number of optimization variables, gradients of the loss function and constraints can be computed using AD, thus providing access to scalable gradient-based optimization algorithms.

An alternative way to transform the ODE into dynamic constraints is to use global parameterization of the state vector, where the solutions of the state and algebraic variable vectors are represented using expansions in terms of basis functions. In one example, the state vector x(t) can be approximated using the expansion:

$$x ( t ) \approx \hat{x} ( t ) = {\sum }_{j = 0}^{n} {a}_{j} {T}_{j} ( t ) , \qquad ( 16 )$$

where Tⱼ are basis functions. One possible choice for the basis functions is the Chebyshev polynomials, defined as Tⱼ(t)=cos(j arccos(t)), that satisfy the following orthogonality relation:

$${\int }_{- 1}^{1} {T}_{j} ( t ) {T}_{i} ( t ) {( 1 - {t}^{2} )}^{- \frac{1}{2}} d t = {N}_{ji} {δ}_{ji} , \qquad ( 17 )$$

with N₀₀=π and

$${N}_{r r} = \frac{π}{2} ,$$

if r≠0 and δⱼᵢ are the Kronecker delta function. To extend the domain beyond the interval [−1,1] , a variable transformation can be performed. For example, the time variable can be converted according to

$$\hat{t} = \frac{2 t - a - b}{b - a} , where t ∈ [ a \cdot b ] .$$

This way, the model dynamic constraints can be reformulated in terms of the polynomial expansions, with the number of terms depending on the number of time samples. Note that in the case of Chebyshev polynomial expansions, there is an optimal number of time samples (referred to as nodes) given the number of terms in the expansion. Using this global-parameterization approach, the parameter-calibration problem can be formulated as:

$$( T , p , {a}_{i} , {b}_{i} ) , \qquad ( 18 )$$

$$\hat{\dot{x}} ( {t}_{j} ) = f ( \hat{x} ( {t}_{j} ) , \hat{z} ( {t}_{j} ) ) ; p , \qquad ( 19 )$$

$$g ( \hat{x} ( {t}_{j} ) , \hat{z} ( {t}_{j} ) ; p ) = 0 , j = 0 , … , n - 1 , \qquad ( 20 )$$

$$\hat{x} ( {t}_{j} ) = {\sum }_{i = 0}^{n} {a}_{i} {T}_{i} ( {t}_{j} ) , j = 0 , … , n , \qquad ( 21 )$$

$$\hat{z} ( {t}_{j} ) = {\sum }_{i = 0}^{n} {b}_{i} {T}_{i} ( {t}_{j} ) , j = 0 , … , n . \qquad ( 22 )$$

Since \hat{\dot{x}} (t) can be evaluated analytically in terms of the vector coefficients aᵢ, the gradients of the loss function and constraints can be computed using AD, thus enabling the use of various gradient-based optimization methods, which scale well with the number of optimization variables.

In addition to Chebyshev expansion, interpolation schemes (e.g., Lagrange interpolation) can also be used for global parameterization. Moreover, neural networks (NNs) can also be used to represent the state and algebraic vectors, such as x(t)=nn(t;wₓ) and z(t)=nn(t;w_{z}) , where nn refers to a neural network (NN) map, and wₓ and w_{z} are the weights of the NNs. There is no formal approach to designing NNs to best approximate the DAE solution. In some embodiments, the optimization system can automatically perform a hyperparameter search that explores different NN architectures, using various hyperparameter optimization frameworks (e.g., Optuna). Unlike the Chebyshev expansion, the NN-based parameterization does not provide error guarantees. However, the NN-based parameterization can be easily implemented in various deep-learning optimization platforms (e.g., Pytorch), and AD can be used again to evaluate the time derivatives of the state vector.

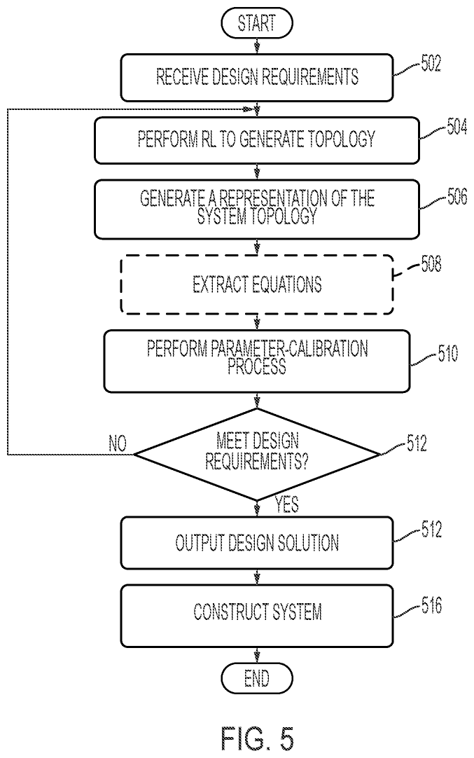

FIG. 5 presents a flowchart illustrating an exemplary process for designing and constructing a physical system, according to one embodiment. During operation, an automated design system can receive a set of design requirements of a to-be-designed physical system (operation 502). The set of design requirements include both qualitative requirements and quantitative requirements. The qualitative requirements can include the functional description or purpose of the to-be-designed physical system. For example, the qualitative requirements may specify that the to-be-designed system is an analog electrical circuit, a digital electrical circuit, a mechanical system, an HVAC system, a heating system, a cooling system, an amine-treating system, etc. The quantitative requirements of a to-be-designed physical system can specify, in quantity, certain criteria to be met by the designed physical systems. For example, if the to-be-designed system is an analog electrical system, the quantitative requirements can include the voltage or current response of the system. In some embodiments, the design requirements may also specify the greatest number of components to be included in the designed system.

Subsequent to receiving the design requirements, the automated design system can perform a reinforcement learning (RL) process to generate a system topology based on an initial topology (operation 504). The initial topology can correspond to the type of the to-be-designed system, and components within the topology can include generalized or universal components that can be instantiated into any component useful in the designed system. In some embodiments, the topology of the to-be-designed system can be represented as an undirected graph, with the links in the graph being the physical components and the nodes in the graph being the connections among the components. For example, the initial topology of an analog or digital circuit can be a grid-like structure with the links being the generalized components and the nodes being the electrical components. A generalized component can include a plurality of switches with each switch coupled to a possible type of component. The automated design system can activate a particular type of component at a particular link by toggling the switches.

In some embodiments, performing the RL process can include training a DNN corresponding to the action-value function or Q-function (e.g., as defined in Equation (4)). In one embodiment, training the DNN can involve minimizing a loss function (e.g., as defined in Equation (5)).

Subsequent to generating the system topology, the automated design system can generate a representation of the RL-generated system using a modeling language as a model of the to-be-designed system (operation 506). For example, the topology of the to-be-designed system can be represented as a Modelica model, and each generalized component can be represented using switches and components within the Modelica library. In some embodiments, nodes in the Modelica model can be generated using the Modelica “connect” command.

The automated design system can optionally extract a set of equations from the system model (operation 508). These extracted equations govern the behavior of the physical system. In situations where the topology is expressed as a Modelica model, extracting the equations can include the operations of converting the Modelica model into XML format (e.g., by using the “dumpXMLDAE” command”, removing hierarchy from the model to create a flat version of the model, extracting equations from the XML file (e.g., by replacing the “connect” statements with equations), and simplifying the model by removing trivial questions (e.g., by using Gaussian elimination).

The automated design system can subsequently perform a parameter-calibration process to determine the optimal value of the parameters of components in the current system topology (operation 510). When there is no extracted equation (i.e., when operation 508 is omitted), performing the parameter-calibration process can involve using the black-box optimization scheme where the system model is integrated into the optimization problem using the FMU. The automated design system can use the FMU to simulate the system model, evaluate the optimization cost function, and update the optimization variables. When equations are extracted from the system model, performing the parameter-calibration process can involve using the white-box optimization scheme where the system dynamics (i.e., the extracted equations are explicitly used as constraints in the optimization process).

In some embodiments, when using the extracted equations as constraints to the parameter-calibration problem, the automated design system can either call ODE solvers (as indicated by Equation (11)) to evaluate the loss function or transform the ODE into a set of dynamic constraints (e.g., by using local or global parameterization of the state vector). The local-parameterization approach is formulated in expressions (13)-(15), and the global-parameterization approach is formulated in expressions (18)-(22).

Subsequent to calibrating the component parameters, the automated design system can determine if the current design solution (i.e., the current RL-generated topology with the optimized parameters) meets the design requirements (operation 512). In some embodiments, the automated design system can compare the quantitative design requirements with the quantitative behavior of the design solution (e.g., as simulated by the system model) and determine whether the difference is within a predetermined threshold. If so, the automated design system can determine that the design solution meets the design requirements and outputs the design solution (operation 514). If the design requirements are not met, the automated design system uses RL to update the system topology (operation 504). In the new round of the RL, the optimal loss function can be computed based on the current component parameters, and the reward can be computed according to Equation (1).

One can subsequently construct the system based on the output of the design solution (operation 516). For example, if the design solution is an analog circuit, one can construct the analog circuit by first selecting circuit components with optimized parameters according to the parameter values specified by the design solution and then connecting the selected circuit components according to the topology specified by the design solution.

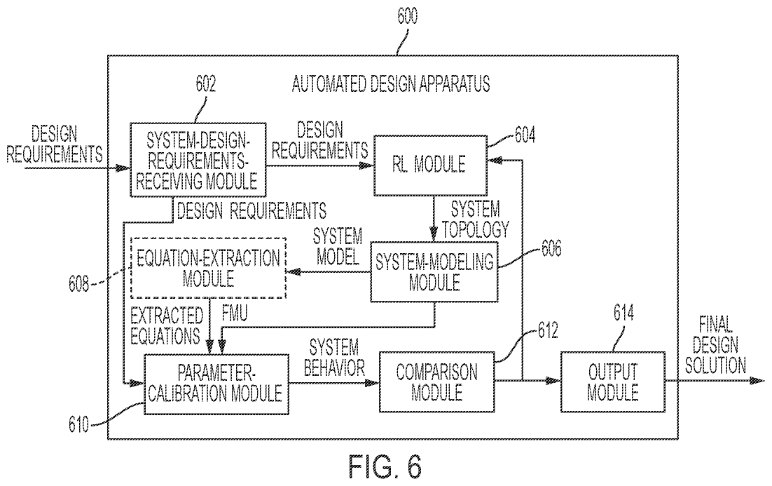

FIG. 6 presents a block diagram of an exemplary automated system-design apparatus, according to one embodiment. Automated system-design apparatus 600 can include a system-design-requirements-receiving module 602, an RL module 604, a system-modeling module 606, an optional equation-extraction module 608, a parameter-calibration module 610, a comparison module 612, and an output module 614.

System-design-requirements-receiving module 602 can be responsible for receiving design requirements of a to-be-designed physical system, including both qualitative and quantitative design requirements. RL module 604 can be responsible for applying an RL algorithm to generate the topology of the to-be-designed system based on the received design requirements. System-modeling module 606 can be responsible for formulating the RL-generated system topology into a model of the to-be-designed physical system. In some embodiments, the system model can be represented using an object-oriented modeling language (e.g., Modelica), and system-modeling module 606 can include a modeling platform (e.g., OpenModelica). Equation-extraction module 608 can be responsible for extracting equations that govern the behavior of the physical system from the model.

Parameter-calibration module 610 can be responsible for calibrating or optimizing the parameters of the components in the system topology based on the design requirements. Parameter-calibration module 610 can perform the optimization either based on the extracted equations (i.e., using the equations as constraints to the optimization) or based on the FMU (which can be generated from the simplified model). Comparison module 612 can be responsible for comparing the behavior of the physical system according to an intermediate design solution with the design requirements. Output module 614 can be responsible for outputting the final design solution.

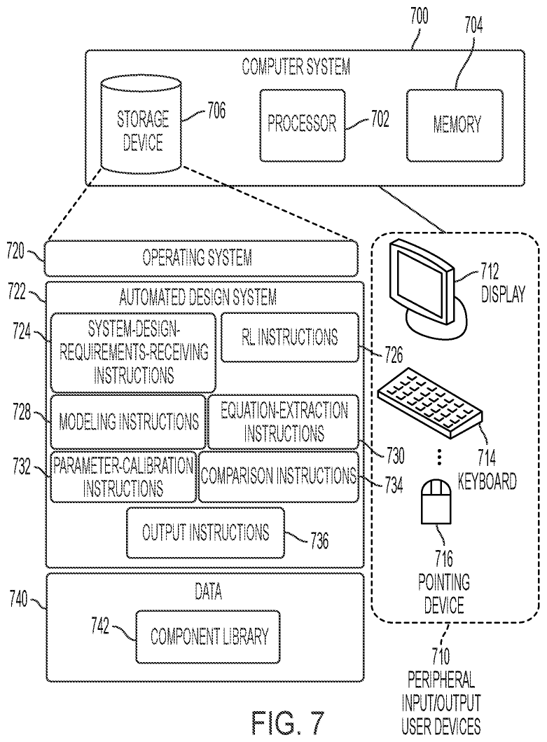

FIG. 7 illustrates an exemplary computer system that facilitates automated design of physical systems, according to one embodiment. Computer system 700 includes a processor 702, a memory 704, and a storage device 706. Furthermore, computer system 700 can be coupled to peripheral input/output (I/O) user devices 710, e.g., a display device 712, a keyboard 714, and a pointing device 716. Storage device 706 can store an operating system 720, an automated design system 722, and data 740. In some embodiments, computer system 700 can implement a design platform that allows a user to generate, according to a set of design requirement, a design solution for a physical system using the design platform. In some embodiments, this design platform can also interface with other platforms (e.g., a Modelica platform, a deep-learning platform, etc.) to facilitate the design of the physical system.

Automated design system 722 can include instructions, which when executed by computer system 700, can cause computer system 700 or processor 702 to perform methods and/or processes described in this disclosure. Specifically, automated design system 722 can include instructions for receiving system design requirements (system-design-requirements-receiving instructions 724), instructions for using an RL-based approach to generate a system topology (RL instructions 726), instructions for modeling the physical system based on the RL-generated topology (modeling instructions 728), optional instructions for extracting equations from the system model (equation-extraction instructions 730), instructions for calibrating the component parameters (parameter-calibration instructions 732), instructions for comparing the simulated behavior of a designed system with the system design requirements (comparison instructions 734), and instructions for outputting the final design solution (output instructions 736). Data 740 can include a component library 742.

In general, the disclosed embodiments provide a system and method that facilitate automated design of physical systems. More specifically, reinforcement learning (RL)-based optimization techniques and gradient- or non-gradient-based optimization (e.g., by using nonlinear programming) techniques can be combined, with the RL being used to generate or select the topology of the to-be-designed system and the gradient-free or gradient-based optimization being used to determine parameters of components in the system topology. For simplicity of implementation, the RL-based topology-selection process can involve using a DQN approach to solve the RL problem. The RL-generated system topology can be represented using a standard modeling language (e.g., Modelica) as a model of the physical system. The gradient-free parameter-optimization process simulates the system behavior using an FMU generated based on the system model. The gradient-based parameter-optimization process computes the gradients of the loss function based on equations extracted from the system model. The gradient-free parameter-optimization process is straightforward but does not scale well with the size of the physical system. The gradient-based parameter-optimization process treats the system dynamics as constraints and uses AD to compute the gradient of the loss function and constraints.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium.

Furthermore, the methods and processes described above can be included in hardware modules or apparatus. The hardware modules or apparatus can include, but are not limited to, application-specific integrated circuit (ASIC) chips, field-programmable gate arrays (FPGAs), dedicated or shared processors that execute a particular software module or a piece of code at a particular time, and other programmable-logic devices now known or later developed. When the hardware modules or apparatus are activated, they perform the methods and processes included within them.

The foregoing descriptions of embodiments of the present invention have been presented for purposes of illustration and description only. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed s:

1. A computer-implemented method for automated design of a physical system, the method comprising:
obtaining design requirements associated with the physical system;
iteratively performing, by a computer, a reinforcement learning (RL) process and a nonlinear optimization process to generate a design solution, wherein the RL process generates a topology represented as a model of the physical system using a modeling language, wherein the generated topology specifies a number of components and connections among the components, and wherein the nonlinear optimization process determines parameters of the components in the topology based on the model and a loss function; and
providing the design solution of the physical system based on the generated topology and the determined parameters of the components, thereby facilitating construction of the physical system.

2. The method of claim 1, wherein performing the RL process comprises defining a reward function that encourages sparsity.

3. The method of claim 1, wherein the generated topology comprises a plurality of generalized components, wherein a respective generalized component comprises a plurality of switches, with each switch coupled to a component of a particular type, thereby allowing the RL process to select a type of the generalized component by acting on the switches.

4. The method of claim 1, wherein using the nonlinear optimization process to determine parameters of the components comprises:
generating a Functional Mockup Unit (FMU); and
determining the parameters of the components using a gradient-free or gradient-approximation optimization process, which comprises simulating the model and computing the loss function using the FMU.

5. The method of claim 1, wherein using the nonlinear optimization process to determine parameters of the components comprises:
extracting a set of equations from the model, wherein the equations specify relationships between a state vector, an algebraic-variables vector, and a parameter vector comprising parameters of the components; and
determining the parameters of the components based on the extracted set of equations using a gradient-based optimization process.

6. The method of claim 5, wherein determining the parameters of the components further comprises:
computing a gradient of the loss function by using an ordinary differential equation (ODE) solver to solve the extracted equations.

7. The method of claim 5, wherein determining the parameters of the components further comprises transforming the extracted set of equations into a set of constraints used in the optimization process.

8. The method of claim 7, wherein transforming the equations into the constraints comprises performing local parameterization by approximating the state vector using a polynomial between adjacent time instants.

9. The method of claim 7, wherein transforming the equations into the constraints comprises performing global parameterization by approximating the state vector using a set of orthogonal basis functions.

10. The method of claim 1, wherein performing the RL process comprises training a deep neural network (DNN).

11. A computer system for automated design of a physical system, the computer system comprising:
a processor; and
a storage device coupled to the processor and storing instructions, which when executed by the processor cause the processor to perform a method, the method comprising:
obtaining design requirements associated with the physical system;
iteratively performing a reinforcement learning (RL) process and a nonlinear optimization process to generate a design solution, wherein the RL process generates a topology represented as a model of the physical system using a modeling language, wherein the generated topology specifies a number of components and connections among the components, and wherein the nonlinear optimization process determines parameters of the components in the topology based on the model and a loss function; and
providing a design solution of the physical system based on the generated topology and the determined parameters of the components, thereby facilitating construction of the physical system.

12. The computer system of claim 11, wherein performing the RL process comprises defining a reward function that encourages sparsity.

13. The computer system of claim 11, wherein the generated topology comprises a plurality of generalized components, wherein a respective generalized component comprises a plurality of switches, with each switch coupled to a component of a particular type, thereby allowing the RL process to select a type of the generalized component by acting on the switches.

14. The computer system of claim 11, wherein using the nonlinear optimization process to determine parameters of the components comprises:
generating a Functional Mockup Unit (FMU); and
determining the parameters of the components using a gradient-free or gradient-approximation optimization process, which comprises simulating the model and computing the loss function using the FMU.

15. The computer system of claim 11, wherein using the nonlinear optimization process to determine parameters of the components comprises:
extracting a set of equations from the model, wherein the equations specify relationships between a state vector, an algebraic-variables vector, and a parameter vector comprising parameters of the components; and
determining the parameters of the components based on the extracted set of equations using a gradient-based optimization process.

16. The computer system of claim 15, wherein determining the parameters of the components further comprises:
computing a gradient of the loss function by using an ordinary differential equation (ODE) solver to solve the extracted equations.

17. The computer system of claim 15, wherein determining the parameters of the components further comprises transforming the extracted set of equations into a set of constraints used in the optimization process.

18. The computer system of claim 17, wherein transforming the equations into the constraints comprises performing local parameterization by approximating the state vector using a polynomial between adjacent time instants.

19. The computer system of claim 17, wherein transforming the equations into the constraints comprises performing global parameterization by approximating the state vector using a set of orthogonal basis functions.

20. The computer system of claim 11, wherein performing the RL process comprises training a deep neural network (DNN).
